(19) United States
(12) Patent Application Publication
(10) Pub. No.: US 2026/0068371 A1
(43) Pub. Date: Mar. 5, 2026

(54) TRANSPARENT DISPLAY DEVICE AND DISPLAY WINDOW

(71) Applicant: AUO Corporation, Hsinchu City (TW)

(72) Inventor: Jui-Ping Yu, Hsinchu City (TW)

(73) Assignee: AUO Corporation, Hsinchu City (TW)

(21) Appl. No.: 18/945,483

(22) Filed: Nov. 12, 2024

(30) Foreign Application Priority Data
Sep. 3, 2024 (TW) 113133293

(51) Int. Cl. H01L 33/50; H01L 25/16

(52) U.S. Cl. CPC H10H 20/8515; H10H 20/8513

(57) ABSTRACT

A transparent display device includes a transparent substrate, a circuit layer, a light-emitting element, and a wavelength conversion layer. The circuit layer is disposed on the transparent substrate, and the light-emitting element is adapted to emit visible light and is disposed on the circuit layer. The light-emitting element and the wavelength conversion layer are respectively disposed on two opposite sides of the circuit layer. The wavelength conversion layer is adapted to convert the visible light into infrared light or ultraviolet light. A display window is also provided.

### CROSS-REFERENCE TO RELATED APPLICATION

This application claims the priority benefit of Taiwan application serial no. 113133293, filed on Sep. 3, 2024. The entirety of the above-mentioned patent application is hereby incorporated by reference herein and made a part of this specification.

### BACKGROUND

### Technical Field

The disclosure relates to a display device, and particularly relates to a transparent display device and a display window.

### Description of Related Art

The transparent display device may display images and has transparency at the same time, so the user's sight may observe the scenery on the backlight side of the transparent display device, making the transparent display device applicable to special display fields. For example, augmented reality (AR) displays, Interactive Transparent Windows or smart car windows have great development prospects.

However, the light leakage problem on the non-display side (also known as the backside) of the transparent display device will affect the background image or vision observed by viewers on the non-display side. When the transparent display device is used in the smart windows or smart car windows, it is also easy to cause organisms (such as insects or birds) on the non-display side (such as outside the window) to be difficult to detect, causing birds or insects to hit the smart window during flight and cause accidents. In addition to affecting the ecology, it is also easy to cause damage to the smart windows.

### SUMMARY

The disclosure provides a transparent display device that may effectively suppress light leakage from the non-display side of the transparent display device.

The disclosure provides a display window, which not only has a display function, but also may reduce the probability of birds accidentally hitting the window.

An embodiment of the disclosure provides a transparent display device, including a transparent substrate, a circuit layer, a light-emitting element, and a wavelength conversion layer. The circuit layer is disposed on the transparent substrate, and the light-emitting element is adapted to emit visible light and is disposed on the circuit layer. The light-emitting element and the wavelength conversion layer are respectively disposed on two opposite sides of the circuit layer. The wavelength conversion layer is adapted to convert the visible light into infrared light or ultraviolet light.

An embodiment of the disclosure provides a display window, including a transparent substrate, a circuit layer, a light-emitting element, and a wavelength conversion layer. The circuit layer is disposed on the transparent substrate, and the light-emitting element is adapted to emit visible light and is disposed on the circuit layer. The light-emitting element and the wavelength conversion layer are respectively disposed on two opposite sides of the circuit layer. The wavelength conversion layer is adapted to convert the visible light into infrared light or ultraviolet light. The wavelength conversion layer includes a first wavelength conversion layer and a second wavelength conversion layer. The first wavelength conversion layer includes a first conversion material having a first particle diameter. The second wavelength conversion layer includes a second conversion material having a second particle diameter. The first wavelength conversion layer is disposed between the transparent substrate and the second wavelength conversion layer, and the first particle diameter is different from the second particle diameter.

In summary, in the transparent display device of the disclosure, the light-emitting element and the wavelength conversion layer are respectively disposed on the two opposite sides of the circuit layer, so that it allows part of the light beam emitted by the light-emitting element to be converted into infrared light or ultraviolet light when transmitted to the non-display side (for example, the backlight side). Since infrared light and ultraviolet light are in wavebands that may not be observed by the human eye, the backside light leakage problem of the transparent display device may be improved. Therefore, when the observer is located on the non-display side of the transparent display device, the environmental scene viewed through the transparent display device may be clearer and the transparency effect is better.

In addition, in the smart window of the disclosure, since the electromagnetic waves in the infrared light waveband and ultraviolet light waveband may not be observed by the human eye, but the ultraviolet light waveband may be observed by some birds or insects, birds or insects may also easily detect the existence of the smart window, so that the probability of birds or insects hitting the smart window may be reduced in addition to solving the above-mentioned backlight leakage problem. Compared with conventional smart windows, the smart window of the disclosure does not affect the ecology and further reduces the chance of damage to the smart window.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic top view of a transparent display device according to an embodiment of the disclosure.

FIG. 2A is a schematic cross-sectional view of a transparent display device according to an embodiment of the disclosure. FIG. 2A corresponds to the cross-section line I-I′ depicted in FIG. 1.

FIG. 2B is an enlarged schematic view of the area A depicted in FIG. 2A.

FIG. 3A is a schematic cross-sectional view of a transparent display device according to an embodiment of the disclosure.

FIG. 3B is an enlarged schematic view of the area A depicted in FIG. 3A.

FIG. 4 is a schematic cross-sectional view of a display window according to an embodiment of the disclosure.

### DESCRIPTION OF THE EMBODIMENTS

Reference will now be made in detail to the present preferred embodiments of the disclosure, examples of which are illustrated in the accompanying drawings. Whenever possible, the same reference numbers are used in the drawings and descriptions to refer to the same or like parts.

It should be understood that when an element such as a layer, film, region, or substrate is referred to as being “on” or “connected to” another element, it may be directly on or connected to another element, or intervening elements may also be present. In contrast, when an element is referred to as being “directly on” or “directly connected to” another element, no intervening elements are present. As used herein, “connected” may refer to a physical connection and/or electrical connection. Furthermore, “electrical connection” or “coupling” may mean the presence of other elements between two elements.

The term “about,” “approximately,” or “substantially” as used herein is inclusive of the stated value and means within an acceptable range of deviation for the particular value as determined by people having ordinary skill in the art, considering the measurements in question and the error associated with measurement of the particular quantity (i.e., the limitations of the measurement system). For example, “about” may mean within one or more standard deviations, for example, within ±30%, ±20%, ±10%, ±5% of the stated value. Furthermore, a relatively acceptable range of deviation or standard deviation may be chosen for the terms “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms such as those defined in the commonly used dictionaries, should be interpreted as having a meaning that is consistent with their meaning in the context of the relevant art and the invention, and will not be interpreted in an idealized or overly formal sense unless expressly so defined herein.

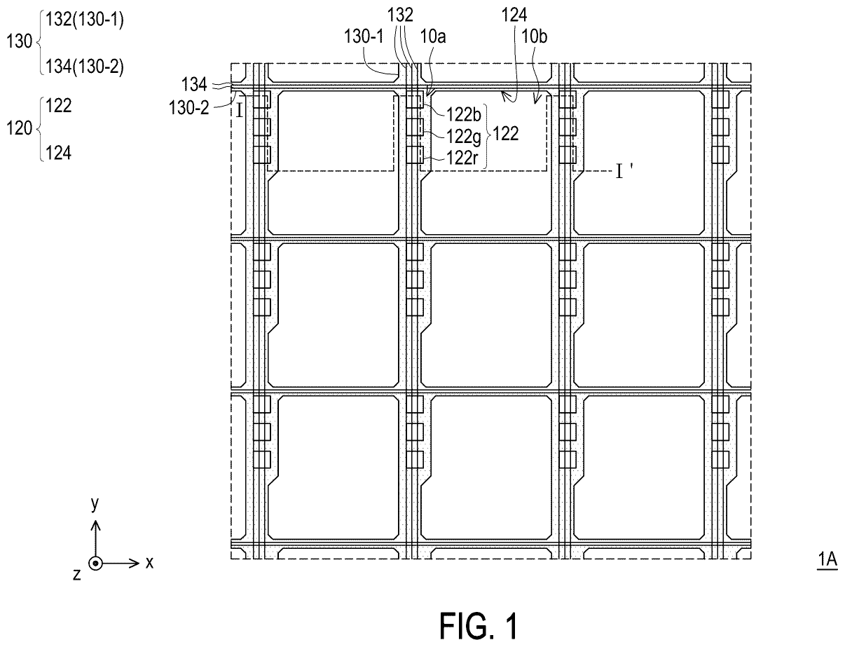

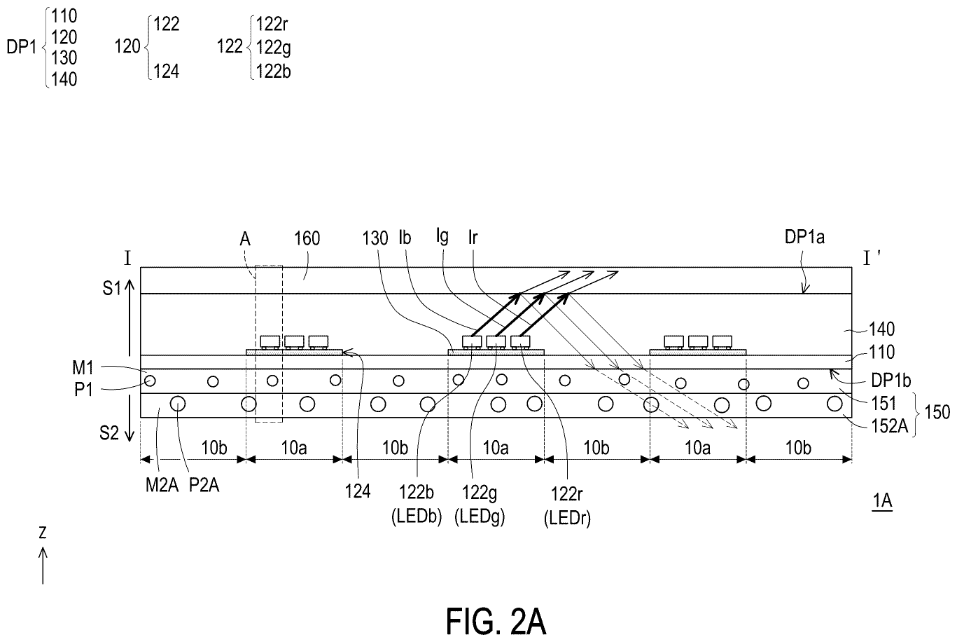

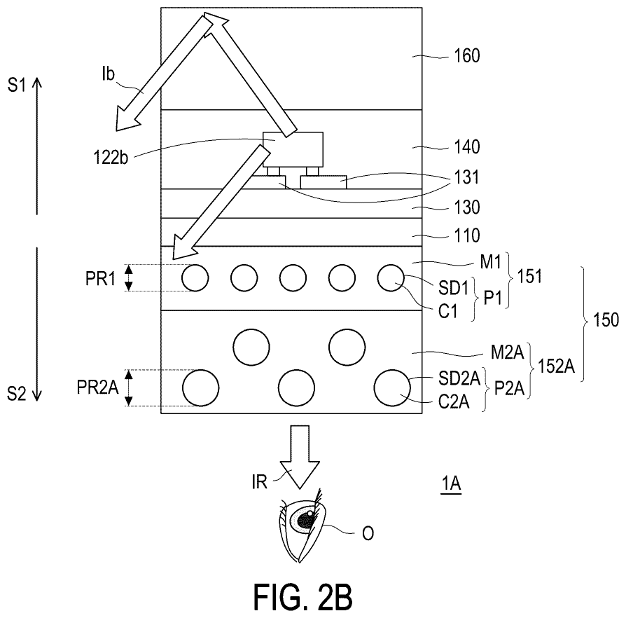

FIG. 1 is a schematic top view of a transparent display device according to an embodiment of the disclosure. FIG. 2A is a schematic cross-sectional view of a transparent display device according to an embodiment of the disclosure. FIG. 2A corresponds to the cross-section line I-I′ depicted in FIG. 1. Referring to FIG. 1 and FIG. 2A, a transparent display device 1A includes a transparent display panel DP1. The transparent display panel DP1 includes a transparent substrate 110, a pixel array 120, a circuit layer 130, an encapsulation layer 140, a wavelength conversion layer 150, and a cover plate 160. The pixel array 120 is disposed on the circuit layer 130 and disposed with a plurality of light-emitting elements, such as a first light-emitting element LEDr, a second light-emitting element LEDg, and a third light-emitting element LEDb. It can also be understood that a first light-emitting element 122r, a second light-emitting element 122g, and a third light-emitting element 122b are disposed on the circuit layer 130.

The circuit layer 130 is disposed on the transparent substrate 110. The circuit layer 130 includes a plurality of signal lines 132 and 134 and is substantially opaque. Of course, the disclosure is not limited thereto. In some embodiments, in order to achieve high light transmittance, the signal lines 132 and 134 may be made of transparent conductive materials, such as indium tin oxide (ITO) or indium tin zinc oxide (ITZO). The transparent substrate 110 has a plurality of display areas 10a and a plurality of transparent areas 10b outside the plurality of display areas 10a. In an embodiment, the plurality of transparent areas 10b respectively include a plurality of areas of the transparent substrate 110 that are not occupied by the circuit layer 130, and the plurality of display areas 10a respectively include a plurality of areas of the transparent substrate 110 that are occupied by the circuit layer 130. For example, in an embodiment, in the top view of the transparent display device 1A, the circuit layer 130 generally has a mesh structure. The mesh structure includes a plurality of longitudinal portions 130-1 and a plurality of transverse portions 130-2 that intersect with each other, the plurality of display areas 10a may be disposed at a plurality of intersections respectively corresponding to the plurality of longitudinal portions 130-1 and the plurality of transverse portions 130-2, and the plurality of transparent areas 10b may respectively correspond to plurality of meshes of the mesh structure, but the disclosure is not limited thereto. The transparent substrate 110 may be made of a transparent material, such as glass, a polymer with high visible light transmittance, a transparent printed circuit board, etc., but the disclosure is not limited thereto. Through the arrangement of the plurality of transparent areas 10b and the mesh-structured circuit layer 130, the proportion of the display light beam emitted by the transparent display device 1A being blocked may be further reduced, so that the light transmittance of the transparent display device 1A may be effectively improved.

The pixel array 120 is disposed on the first transparent substrate 110. The pixel array 120 includes a plurality of pixels 122 and a plurality of openings 124. The plurality of pixels 122 are arranged in an array along a first direction y and a second direction x, where the first direction y and the second direction x intersect. For example, in an embodiment, the first direction y and the second direction x may be substantially perpendicular to each other, but the disclosure is not limited thereto. Each pixel 122 overlaps with a corresponding display area 10a in a third direction z, where the third direction z is perpendicular to the first direction y and the second direction x. Each opening 124 is surrounded by the plurality of pixels 122, and each opening 124 overlaps with a corresponding transparent area 10b in the third direction z. For example, in an embodiment, each opening 124 may be a closed opening, but the disclosure is not limited thereto.

In an embodiment, each pixel 122 may include a plurality of sub-pixels 122r, 122g, and 122b respectively used to emit a first color light lr, a second color light lg, and a third color light lb. For example, in an embodiment, the sub-pixels 122r, 122g, and 122b respectively include the first light-emitting element LEDr, the second light-emitting element LEDg, and the third light-emitting element LEDb. The wavelengths of the first color light lr, the second color light lg, and the third color light lb respectively emitted by the first light-emitting element LEDr, the second light-emitting element LEDg, and the third light-emitting element LEDb may all fall in the visible light waveband (for example, 380 nm to 700nm). The first color light lr, the second color light lg, and the third color light lb may be red light, green light, and blue light respectively, but the disclosure is not limited thereto. In other embodiments not shown, the sub-pixels may also include light-emitting elements that emit yellow light. In some embodiments not shown, the plurality of sub-pixels of the transparent display panel DP1 may all be third light-emitting elements LEDb that emit blue light, and may use the color filter array and the black matrix disposed on a first side S1 of the encapsulation layer 140 to convert the required color light (such as red light, green light, yellow light, etc.), and the disclosure is not limited thereto. In the following, for convenience of explanation, the first side S1 may be regarded as the display side of the transparent display device 1A.

The circuit layer 130 is disposed on the transparent substrate 110, and the plurality of signal lines 132 and 134 of the circuit layer 130 are electrically connected to the plurality of pixels 122. The signal lines 132 and 134 may be any wires used to drive the pixels 122. In an embodiment, the circuit layer 130 also includes a plurality of sub-pixel driving circuits (not shown) and corresponding pads 131. Each of the first light-emitting element LEDr, the second light-emitting element LEDg and the third light-emitting element LEDb of the first pixel 122 is electrically connected to the corresponding pad 131 to be electrically connected to the sub-pixel driving circuit. For example, each sub-pixel driving circuit may include a first transistor (not shown), a second transistor (not shown), and a capacitor (not shown). The second terminal of the first transistor is electrically connected to the control terminal of the second transistor. The capacitor is electrically connected to the second terminal of the first transistor and the first terminal of the second transistor. The first electrode (not shown) of the first light-emitting element LEDr, the second light-emitting element LEDg, or the third light-emitting element LEDb is electrically connected to the second terminal of the second transistor. The plurality of signal lines 132 and 134 may include a data line electrically connected to the first terminal of the first transistor, a scanning line electrically connected to the control terminal of the first transistor, and a power line electrically connected to the first terminal of the second transistor. Of course, the disclosure is not limited thereto. If T and C are used to represent the transistor and capacitor in the sub-pixel driving circuit respectively, then the sub-pixel driving circuit may be a 1T1C architecture, a 2T1C architecture, a 3T1C architecture, a 3T2C architecture, a 4T1C architecture, a 4T2C architecture, a 5T1C architecture, a 5T2C architecture, a 6T1C architecture, a 6T2C architecture, or any possible pixel circuit architecture used to drive the first light-emitting element LEDr, the second light-emitting element LEDg, or the third light-emitting element LEDb, but is not limited thereto.

In the embodiment, the first light-emitting element LEDr, the second light-emitting element LEDg, and the third light-emitting element LEDb are, for example, micro light-emitting diode elements (μLEDs), but are not limited thereto. In other embodiments, the first light-emitting element LEDr, the second light-emitting element LEDg, or the third light-emitting element LEDb may also be an organic light-emitting diode (OLED) or a mini-LED among light-emitting diodes (LEDs).

Referring to FIG. 2A, in an embodiment, the transparent display panel DP1 further includes the encapsulation layer 140 disposed on the transparent substrate 110 and covering the plurality of pixels 122. The encapsulation layer 140 has a light-emitting surface DP1a of the transparent display panel DP1, and the light-emitting surface DP1a faces away from the pixels 122. Most of the first color light lr, the second color light lg, and the third color light lb emitted by the first light-emitting element LEDr, the second light-emitting element LEDg, and the third light-emitting element LEDb of the transparent display panel DP1 leave the transparent display panel DP1 through the light-emitting surface DP1a, thereby providing a display image to the user. The light-emitting surface DP1a is the front surface of the transparent display panel DP1. The transparent substrate 110 has a back surface DP1b of the transparent display panel DP1, and the back surface DP1b faces away from the pixels 122. For example, in the embodiment, the encapsulation layer 140 may contact the circuit structure 130 and the plurality of pixels 122, and may serve as an encapsulation layer for encapsulating the circuit structure 130 and each pixel 122. The encapsulation layer 140 may be used as a barrier layer for air or moisture to prevent air or moisture from invading the circuit structure 130 and each pixel 122. The material of the encapsulation layer 140 may be epoxy resin, a polymer with high visible light transmittance, optically clear adhesive (OCA), etc., but the disclosure is not limited thereto.

The wavelength conversion layer 150 is disposed on the back surface DP1b of the transparent display panel DP1. Specifically, the first light-emitting element LEDr, the second light-emitting element LEDg, and the third light-emitting element LEDb are disposed on the first side S1 of the circuit layer 130, and the wavelength conversion layer 150 is disposed on a second side S2 of the circuit layer 130. Furthermore, in the transparent display device 1A, when the visible light emitted by the first light-emitting element LEDr, the second light-emitting element LEDg, and the third light-emitting element LEDb is transmitted toward the second side S2 due to total reflection, light leakage, or reflection, the wavelength conversion layer 150 is adapted to convert the visible light into electromagnetic waves in the infrared light waveband, thereby improving the backside light leakage problem of the transparent display device 1A. For convenience of explanation, the second side S2 may be regarded as the backside of the transparent display device 1A.

In detail, the wavelength conversion layer 150 may include a wavelength conversion material, such as a fluorescent material, a phosphorescent material, a nanocrystal-coated triplet-triplet annihilation (TTA) emitter, or a quantum dot, and is adapted to absorb electromagnetic waves in the visible light waveband and emit electromagnetic waves with longer wavelengths in the non-visible light waveband. In the embodiment, the wavelength conversion layer 150 may specifically include a first wavelength conversion layer 151 and a second wavelength conversion layer 152A. The first wavelength conversion layer 151 is disposed between the transparent substrate 110 and the second wavelength conversion layer 152A, and the first wavelength conversion layer 151 may include a first conversion material P1 and a first medium M1, and the second wavelength conversion layer 152A may include a second conversion material P2A and a second medium M2A.

In the embodiment, the first conversion material P1 is a quantum dot (QD), which may be used to convert the wavelength of the light emitted by the first light-emitting element LEDr, the second light-emitting element LEDg, and the third light-emitting element LEDb. Furthermore, the quantum dot is a nanometer-scale diameter grain. For example, the diameter is usually between 1 nm and 100 nm. Due to the quantum confinement effect, the energy levels of different electronic states in the quantum dot are related to the diameter and composition of the quantum dot. Thereby, the luminescence spectrum of the quantum dot may be controlled by changing the diameter of the quantum dot.

FIG. 2B is an enlarged schematic view of the area A depicted in FIG. 2A. Referring to FIG. 2B, the first conversion material P1 may be composed of a core C1 and a shell SD1 covering the core C1. The shell SD1 may serve as a protective layer that prevents or reduces chemical changes of the core C1 to maintain semiconductor properties. The shell SD1 may include a single layer or plurality of layers, and may include metal or non-metallic oxides, semiconductor compounds, or a combination thereof, and the disclosure is not limited thereto. In detail, in the embodiment, the core C1 of the first conversion material P1 of the first wavelength conversion layer 151 may include a semiconductor material such as lead sulfide (PbS), cadmium sulfide (CdS), cadmium selenide (CdSe), cadmium telluride (CdTe), indium arsenide (InAs), zinc sulfide (ZnS), and/or indium phosphide (InP). A first particle diameter PR1 of the first conversion material P1 may be equal to or greater than 1 nanometer and equal to or less than 20 nanometers. In some implementations, the first conversion material P1 may be a quantum dot that is adapted for absorbing electromagnetic waves in the visible light waveband (for example, 400 nm to 700 nm) and emitting electromagnetic waves in the near infrared light waveband (for example, 750 nm to 1000 nm). The first medium M1 may be organic polymer plastic or glass, and the disclosure is not limited thereto.

Similarly, the second conversion material P2A of the second wavelength conversion layer 152A may also include a core C2A and a shell SD2A. The materials of the core C2A and the shell SD2A may be the same as the materials of the core C1 and the shell SD1 of the first conversion material P1. Since the diameter of the quantum dot is related to the luminescence spectrum of the quantum dot, it is possible to only adjust the diameters of the first conversion material P1 and the second conversion material P2A to control the wavelength of the electromagnetic wave to be converted, without adjusting the material of the second conversion material P2A. However, in other embodiments, the materials of the core C2A and the shell SD2A may also be different from the materials of the core C1 and the shell SD1 of the first conversion material P1, and the disclosure is not limited thereto.

It is worth mentioning that the first particle diameter PR1 of the first conversion material P1 is different from a second particle diameter PR2A of the second conversion material P2A. In the embodiment, the first particle diameter PR1 is smaller than the second particle diameter PR2A. Since the sizes of the first particle diameter PR1 and the second particle diameter PR2A are positively correlated with the wavelength of the light beam converted by the first wavelength conversion layer 151 and the second wavelength conversion layer 152A, such as the second particle diameter PR2A being larger than the first particle diameter PR1, the wavelength of the light beam converted by the wavelength conversion layer 150 also becomes larger, so the wavelength conversion layer 150 may convert visible light into infrared light. Therefore, the second conversion material P2A may select a quantum dot that is adapted for absorbing electromagnetic waves in the emission spectrum waveband of first conversion material P1 and adapted for emitting electromagnetic waves of longer wavebands. Those skilled in the art may select the electromagnetic waveband to be converted and select appropriate quantum dot materials. By this, when the light beam emitted by the light-emitting element leaks toward the backside (for example, a third color light lb emitted by the sub-pixel 122b depicted in FIG. 2B is transmitted toward the second side S2), the wavelength conversion layer 150 includes two or more light conversion layers (i.e., the first wavelength conversion layer 151 and the second wavelength conversion layer 152A), which is beneficial to converting visible light into infrared light IR in a single direction. Accordingly, since the waveband of the infrared light IR is invisible to human eyes, the backside light leakage observed by an observer O located on the second side S2 of the transparent display device 1A may be effectively reduced. On the other hand, the transparent display device 1A may maintain a certain light transmittance, so that the user located on the first side S1 of the transparent display device 1A may still receive a certain amount of ambient light from the second side S2 when viewing the transparent display device 1A., which is beneficial to maintaining the transparency of the transparent display device 1A.

Hereinafter, other embodiments will be provided to describe the disclosure in detail, wherein the same components will be marked by the same reference numbers, and the description of the same technical contents will be omitted.

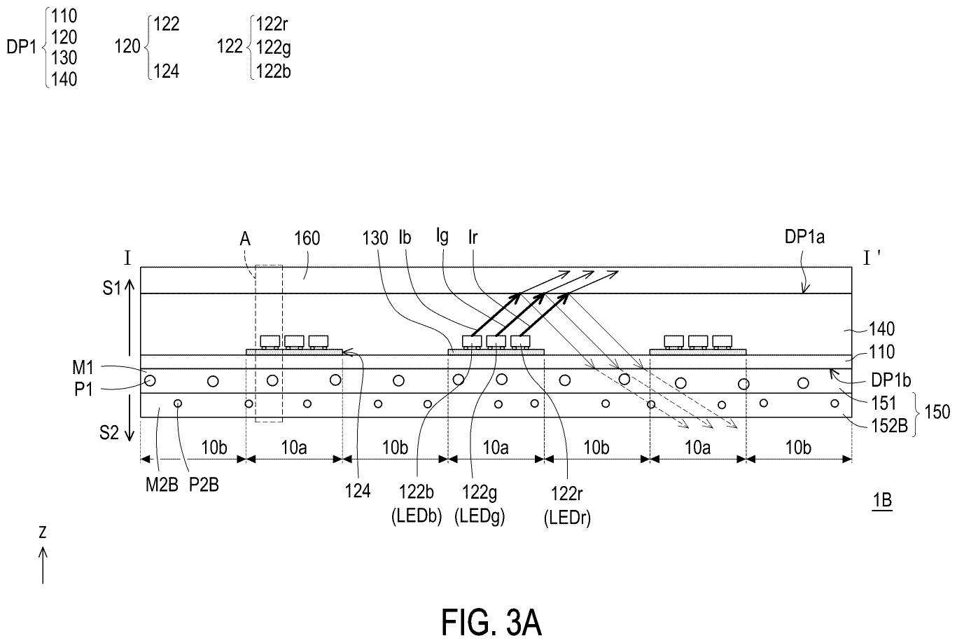

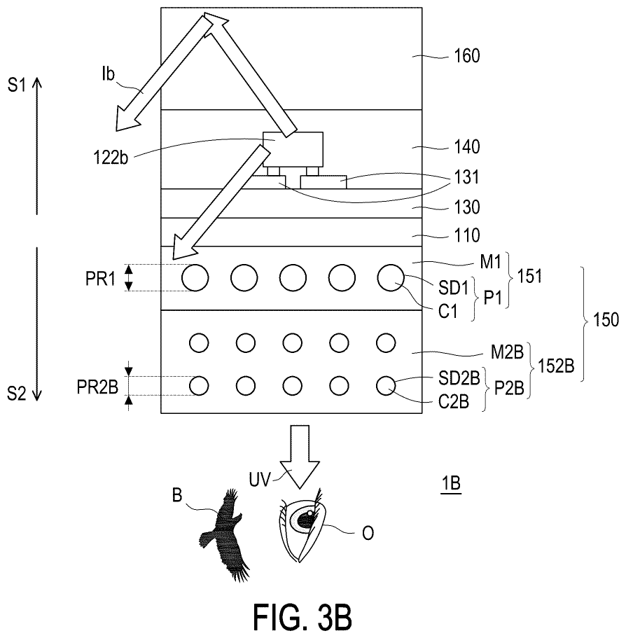

FIG. 3A is a schematic cross-sectional view of a transparent display device according to an embodiment of the disclosure. FIG. 3B is an enlarged schematic view of the area A depicted in FIG. 3A. Referring to FIG. 3A and FIG. 3B at the same time, a transparent display device 1B is similar to the transparent display device 1A depicted in FIG. 2A. The main difference thereof is that the wavelength conversion layer 150 of the transparent display device 1B is adapted to convert visible light into ultraviolet light.

In detail, the second wavelength conversion layer 152B of the wavelength conversion layer 150 of the transparent display device 1B includes a second medium M2B and a second conversion material P2B. The second conversion material P2B may include a core C2B and a shell SD2B covering the core C2B. The material of the shell SD2B and the material of the second medium M2B may be a polymer, an inorganic substance, or a conventional quantum dot dielectric layer material, and the disclosure is not limited thereto. It is worth mentioning that the material of the core C2B is an up conversion material, and the first particle diameter PR1 of the first conversion material P1 is larger than a second particle diameter PR2B of the second conversion material P2B. Similar to the above, since the sizes of the first particle diameter PR1 and the second particle diameter PR2B are positively correlated with the wavelength of the light beam converted by the first wavelength conversion layer 151 and the second wavelength conversion layer 152B, such as the second particle diameter PR2B being smaller than the first particle diameter PR1, the wavelength of the light beam converted by the wavelength conversion layer 150 also becomes smaller, so the wavelength conversion layer 150 may convert visible light or infrared light into ultraviolet light. In some implementations, the second particle diameter PR2B may be greater than or equal to 10 nanometers and less than or equal to 25 nanometers.

In the embodiment, the core C2B includes, for example, an upconversion material such as zinc sulfide, titanium dioxide, or a carbon quantum dot. Therefore, the second conversion material P2B may convert two long-wavelength photons, such as two low-energy infrared light waveband photons, into one short-wavelength photon, such as a high-energy visible light waveband photon, or the second conversion material P2B may also convert two low-energy visible light photons into one high-energy ultraviolet light photon. Therefore, when the light beam emitted by the light-emitting element leaks toward the backside (for example, a third color light lb emitted by the sub-pixel 122b depicted in FIG. 3B is transmitted toward the second side S2), the wavelength conversion layer 150 includes two or more light conversion layers (i.e., the first wavelength conversion layer 151 and the second wavelength conversion layer 152B), which is beneficial to converting visible light into ultraviolet light UV in a single direction. Accordingly, since the waveband of the ultraviolet light UV is invisible to human eyes, the backside light leakage observed by the observer O located on the second side S2 of the transparent display device 1B may be effectively reduced. On the other hand, the transparent display device 1B may maintain a certain light transmittance, so that the user located on the first side S1 of the transparent display device 1B may still receive a certain proportion of ambient light from the second side S2 when viewing the transparent display device 1B, which is beneficial to maintaining the transparency of the transparent display device 1B.

Not only that, since the eyes of birds or some insects may observe electromagnetic waves in the ultraviolet light waveband, when a bird B is on the backside of the transparent display device 1B, the bird B or the insect may observe the ultraviolet light UV and more easily detect the existence of the transparent display device 1B, making it less likely for the bird or the insect to hit the transparent display device 1B, so that the chance of damage to the transparent display device 1B due to bird collision may be reduced, and the transparent display device 1B is less likely to affect the ecology.

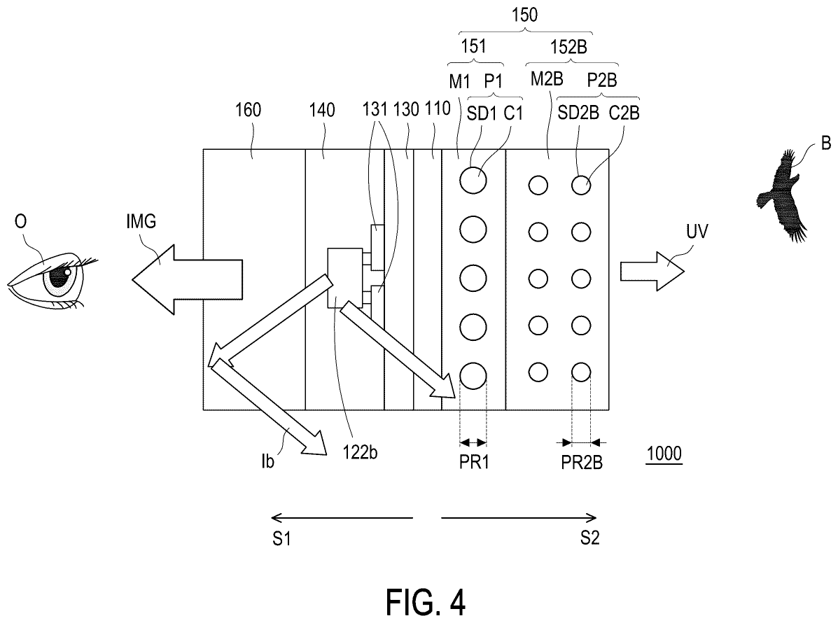

FIG. 4 is a schematic cross-sectional view of a display window according to an embodiment of the disclosure. Referring to FIG. 4, a display window 1000 may include the transparent display device 1A or the transparent display device 1B mentioned above. That is to say, the display window 1000 may include the aforementioned transparent substrate 110, the circuit layer 130, the first light-emitting element LEDr, the second light-emitting element LEDg, the third light-emitting element LEDb, the wavelength conversion layer 150, and the same configuration relationship of each element in the transparent display device 1A or the transparent display device 1B as described above. Furthermore, the wavelength conversion layer 150 of the display window 1000 may be adapted to convert visible light into infrared light (e.g., the transparent display device 1A) or ultraviolet light (e.g., the transparent display device 1B). The wavelength conversion layer 150 is located on the side of the circuit layer 130 facing the outdoor side (for example, the second side S2). In FIG. 4, the display window 1000 includes the transparent display device 1B as an exemplary illustration. Accordingly, the display window 1000 may provide display light IMG for viewing by the observer O located on the indoor side (for example, the first side S1), and is adapted to convert backside light leakage toward the second side S2 into the ultraviolet light UV, so that when applied to the display window 1000 (such as a windshield, a mobile vehicle window, etc.), the transparent display device 1B may be easily noticed by the bird B, thereby reducing the chance of bird collision and less likely to affect the ecology. For relevant functions or technical effects, reference may be made to the above paragraphs, which are not repeated hereafter.

To sum up, in the transparent display device of the disclosure, the light-emitting element and the wavelength conversion layer are respectively disposed on the two opposite sides of the circuit layer, so that it allows part of the light beam emitted by the light-emitting element to be converted into infrared light or ultraviolet light when transmitted to the non-display side (for example, the backlight side). Since infrared light or ultraviolet light is in a waveband that may not be observed by the human eye, the backside light leakage problem of the transparent display device may be improved. Therefore, when the observer is located on the non-display side of the transparent display device, the environmental scene viewed through the transparent display device may be clearer and the transparency effect is better.

In addition, in the smart window of the disclosure, since the electromagnetic waves in the ultraviolet light waveband may not be observed by the human eye, but may be observed by some birds or insects, birds or insects may also easily detect the existence of the smart window, so that the probability of birds or insects hitting the smart window may be reduced in addition to solving the above-mentioned backlight leakage problem. Compared with conventional smart windows, the smart window of the disclosure does not affect the ecology and further reduces the chance of damage to the smart window.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A transparent display device, comprising:
a transparent substrate;
a circuit layer, disposed on the transparent substrate;
a light-emitting element, adapted to emit visible light, and disposed on the circuit layer; and
a wavelength conversion layer, wherein the light-emitting element and the wavelength conversion layer are respectively disposed on two opposite sides of the circuit layer,
wherein the wavelength conversion layer is adapted to convert the visible light into infrared light or ultraviolet light.

2. The transparent display device according to claim 1, wherein the wavelength conversion layer comprises:
a first wavelength conversion layer, comprising a first conversion material having a first particle diameter;
a second wavelength conversion layer, comprising a second conversion material having a second particle diameter, wherein the first wavelength conversion layer is disposed between the transparent substrate and the second wavelength conversion layer, and the first particle diameter is different from the second particle diameter.

3. The transparent display device according to claim 2, wherein the first particle diameter is larger than the second particle diameter, and the wavelength conversion layer is adapted to convert the visible light into the ultraviolet light.

4. The transparent display device according to claim 3, wherein the second conversion material comprises zinc sulfide, titanium dioxide, or a carbon quantum dot.

5. The transparent display device according to claim 2, wherein the first particle diameter is smaller than the second particle diameter, and the wavelength conversion layer is adapted to convert the visible light into the infrared light.

6. The transparent display device according to claim 5, wherein the second conversion material comprises a fluorescent material, a phosphorescent material, a nanocrystal-coated triplet-triplet annihilation emitter, or a quantum dot.

7. The transparent display device according to claim 2, wherein sizes of the first particle diameter and the second particle diameter are positively correlated with a wavelength of a light beam converted by the first wavelength conversion layer and the second wavelength conversion layer.

8. A display window having an indoor side and an outdoor side, the display window comprising:
a transparent substrate;
a circuit layer, disposed on the transparent substrate;
a light-emitting element, adapted to emit visible light, and disposed on the circuit layer; and
a wavelength conversion layer, wherein the light-emitting element and the wavelength conversion layer are respectively disposed on two opposite sides of the circuit layer, and the wavelength conversion layer comprises:
a first wavelength conversion layer, comprising a first conversion material having a first particle diameter; and
a second wavelength conversion layer, comprising a second conversion material having a second particle diameter, wherein the first wavelength conversion layer is disposed between the transparent substrate and the second wavelength conversion layer, and the first particle diameter is different from the second particle diameter,
wherein the wavelength conversion layer is adapted to convert the visible light into infrared light or ultraviolet light.

9. The display window according to claim 8, wherein the wavelength conversion layer is located on a side of the circuit layer facing the outdoor side.
